(19) United States
(12) Patent Application Publication
(10) Pub. No.: US 2008/0054466 A1
(43) Pub. Date: Mar. 6, 2008

(54) SEMICONDUCTOR DEVICE AND METHOD OF MANUFACTURING SEMICONDUCTOR DEVICE

(75) Inventors: Hayato NASU, Ooita-ken (JP); Akihiro Kajita, Kanagawa-ken (JP); Yumi Hayashi, Kanagawa-ken (JP); Takamasa Usui, Tokyo (JP); Kazumichi Tsumura, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/848,978

(22) Filed: Aug. 31, 2007

(30) Foreign Application Priority Data
Aug. 31, 2006 (JP) 2006-236809
Aug. 31, 2006 (JP) 2006-236810

(51) Int. Cl. H01L 23/52; H01L 21/44

(52) U.S. Cl. 257/751; 438/653; 257/E21.476; 257/E23.141

(57) ABSTRACT

In one aspect of the invention, a method of manufacturing a semiconductor device may include providing a first dielectric layer, providing a trench in the first dielectric layer and a wiring layer which has a Cu in the trench, providing a cap layer on a top surface of the wiring layer, the cap layer being conductive and having a Co, and providing a Cu silicide nitride layer on a part of the top surface of the wiring layer, on which the cap layer is not provided.

### CROSS REFERENCE TO RELATED APPLICATION

This application is based upon and claims the benefit of priority from Japanese Patent Application No. 2006-236809, filed on Aug. 31, 2006, and from Japanese Patent Application No. 2006-236810, filed on Aug. 31, 2006, the entire contents of which are incorporated herein by reference.

### BACKGROUND

In a semiconductor device using a Cu wiring, a barrier layer for preventing oxidation is provided between the Cu wiring and a dielectric layer, since signal wiring characteristic may be worsened by an oxidation of the wiring. The barrier layer has a preferably good adhesion to the Cu wiring in order to reduce a degration of the wiring characteristic. The degration may be Electro-Migration (EM) based on Cu diffusing from the Cu wiring.

On the other hand, in a semiconductor device, a cap layer for reducing a degration of the wiring characteristic and improving the EM resistance may be provided on the Cu wiring. The cap layer is formed by electroless plating and has an anti-oxidation property and a Co which is good adhesion to Cu wiring.

### SUMMARY

Aspects of the invention relate to an improved semiconductor device and method of manufacturing a semiconductor device.

In one aspect of the invention, a method of manufacturing a semiconductor device may include providing a first dielectric layer, providing a trench in the first dielectric layer and a wiring layer which has a Cu in the trench, providing a cap layer on a top surface of the wiring layer, the cap layer being conductive and having a Co, and providing a Cu silicide nitride layer on a part of the top surface of the wiring layer, on which the cap layer is not provided.

In one aspect of the invention, a method of manufacturing a semiconductor device may include providing a first dielectric layer, providing a trench in the first dielectric layer and a wiring layer which has a Cu in the trench, providing a first cap layer on a top surface of the wiring layer, the first cap layer being conductive and having a Co, activating at least a part of the top surface of the wiring layer, on which the first cap layer is not provided and providing a second cap layer on the activated part of the wiring layer, the second cap layer being conductive and having a Co.

In one aspect of the invention, a method of manufacturing a semiconductor device may include providing a first dielectric layer, providing a trench in the first dielectric layer and a wiring layer which has a Cu in the trench, providing a Cu silicide nitride layer on a top surface of the wiring layer, providing a cap layer on a top surface of the Cu silicide nitride layer, the cap layer being conductive and having a Co.

In one aspect of the invention, a semiconductor device may include a dielectric layer, a wiring layer provided in the dielectric layer and having a Cu, a cap layer provided on a top surface of the wiring layer, the cap layer being conductive and having a Co, a Cu silicide nitride layer on the wiring layer except for a region where the cap layer is provided on.

In one aspect of the invention, a semiconductor device may include a first wiring member having a metal (M) and having a depression on a top surface, a cap layer provided on a top surface of the first wiring, the cap layer being conductive and having a Co, and a second wiring member provided on the cap layer, and a metal silicide nitride layer having the M as a component provided on a surface of the depression, wherein one of the first wiring member and the second wiring member has a Cu as a main component.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a cross sectional view of a semiconductor device in accordance with a first embodiment.

FIGS. 2A-2E are cross sectional views showing a manufacturing process of a semiconductor device in accordance with the first embodiment.

FIG. 3 is a cross sectional view of a semiconductor device in accordance with a modification of the first embodiment.

FIGS. 4A-4C are cross sectional views showing a manufacturing process of a semiconductor device in accordance with a first modification of the first embodiment.

FIGS. 5A and 5B are cross sectional views showing a manufacturing process of a semiconductor device in accordance with a second modification of the first embodiment.

FIG. 6 is a cross sectional view of a semiconductor device in accordance with a second embodiment.

FIGS. 7A-7F are cross sectional views showing a manufacturing process of a semiconductor device in accordance with the second embodiment.

FIG. 8 is a cross sectional view of a semiconductor device in accordance with a modification of the second embodiment.

FIGS. 9A-9E are cross sectional views showing a manufacturing process of a semiconductor device in accordance with the modification of the second embodiment.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### First Embodiment

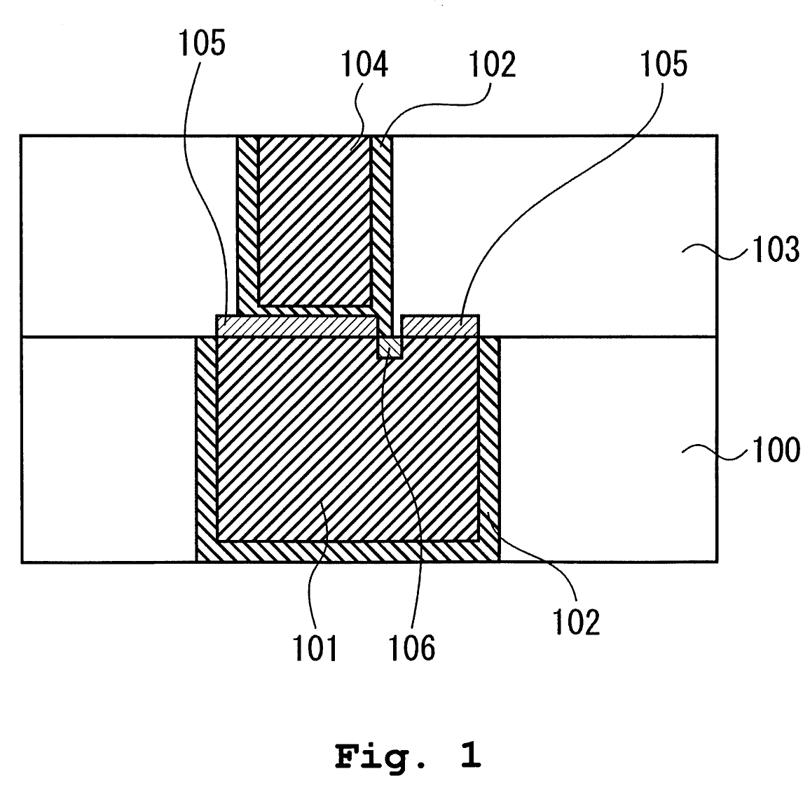

A first embodiment of the present invention will be explained hereinafter with reference to FIG. 1. FIG. 1 is a cross sectional view of a semiconductor device in accordance with a first embodiment.

In this first embodiment, a semiconductor device includes a semiconductor substrate (not shown in FIG. 1), such as a Si substrate, a dielectric layer such as silicon oxide, provided on or above the semiconductor substrate, and a multi wiring structure having a plug or plugs and a wiring layer or wiring layers. In this embodiment, the wiring may be made of Cu or Cu alloy.

As shown in FIG. 1, a wiring layer 101 is provided in a first dielectric layer 100. On a side surfaces and on a bottom surface of the wiring layer 101, a barrier layer 102, which is made of TiN, TaN, Ti, Ta, or the like, is provided. The barrier layer 102 is configured to prevent a Cu diffusing from the wiring layer 101 to the first dielectric layer 100 or a layer provided under the wiring layer 101.

A second dielectric layer 103 is provided on the first dielectric layer 100. A plug 104 is provided in the second dielectric layer 103. The plug 104 is provided above the wiring layer 101 and is electrically connected to the wiring layer 101 and an upper wiring layer (not shown in FIG. 1). The barrier layer 102 is provided on side surfaces and bottom surface of the plug 104.

A cap layer 105 is provided on a top surface of the wiring layer 101. The cap layer 105 (right side in FIG. 1) is provided between the top surface of the wiring layer 101 and the second dielectric layer 103. The cap layer 105 (left side in FIG. 1) is provided between the top surface of the wiring layer 101 and the bottom surface of the plug 104 via the barrier layer 102.

The cap layer 105 is conductive and configured to protect the wiring layer 101 from oxidation. The cap layer 105 has high melting point, and high adhesiveness to the wiring layer 101. The cap layer 105 may be formed by electroless plating and have a Co as a component. The cap layer 105 may be, for example, a Co compound added a metal such as W, CoWB, CoWP, CoWBP, CoBP, CoB, CoP or the like.

The top surface of the wiring 101 is not exposed to oxidation gases, since the cap layer 105 is provided. The wiring 101 is hardly oxidized by invading water, since the cap layer 105 is provided on the top surface of the wiring layer 101. The cap layer 105 is configured to prevent a Cu from diffusing from the wiring layer to the second dielectric layer 103, and the EM resistance may be improved.

As shown in FIG. 1, the cap layer 105 is hardly provided as a uniform thickness layer on the entire top surface of the wiring layer 101. It is hard to cover the top surface of the wiring layer 101 with the cap layer 105, since the void in the cap layer 105 or collapsing in an edge of the wiring layer 101. In other words, on a part of the top surface of the wiring, the cap layer 105 is not provided. The part of the wiring layer 101 which is not covered with the cap layer 105 is oxidized easier, and the EM resistance may be worsened at that part.

In this embodiment, on the part of the wiring layer 101 which is not covered with the cap layer 105, Cu silicide layer including nitrogen or Cu silicide nitride (CuSiN) 106 is provided. The Cu silicide nitride layer is formed such that Cu component provided near the top surface of the wiring layer is silicided and nitridated.

The CuSiN layer 106 may be formed such as the surface of the wiring 101 is exposed to an active gas including Si, such as Silane gas, the Si atom is introduced from the surface to the inside of the wiring layer 101, a Cu silicide layer is created, and an active gas including nitrogen, such as NH₃ is supplied to the Cu by plasma.

The CuSiN 106 has a lower adhesion to the wiring layer 101 than the cap layer 105. However, the CuSiN 106 is capable of being formed easily a uniform thickness and a good film property. So the top surface of the wiring layer 101 is covered with the cap layer 105 and the CuSiN 106. The CuSiN 106 is provided on a part of the wiring layer 101 which the cap layer 105 is not provided on. Therefore, the oxidation and EM of the wiring layer 101 on the surface may be reduced.

In this embodiment, as shown in FIG. 1, the CuSiN 106 is in contact with the second dielectric layer 103. However, the CuSiN 106 mat be covered with the barrier metal 102, and may not be in contact with the second dielectric layer 103.

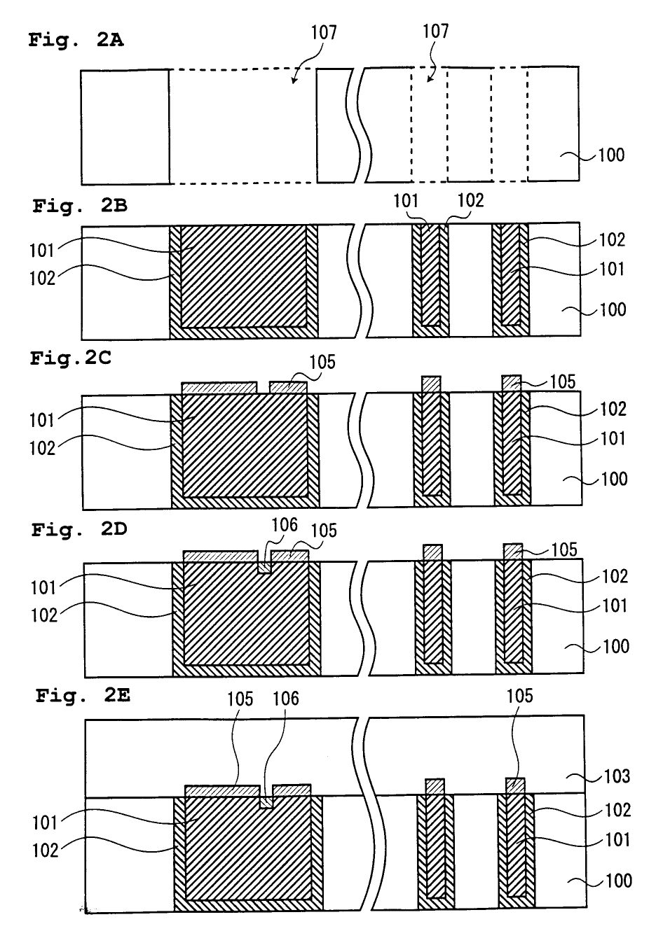

Next, a manufacturing process of the semiconductor device in accordance with the first embodiment will be explained hereinafter. FIGS. 2A-2E are cross sectional views showing a manufacturing process of a semiconductor device in accordance with the first embodiment.

As shown in FIG. 2A, the first dielectric 100 is formed on an interlayer dielectric layer (not shown), which has a wiring and/or plug by CVD (Chemical vapor deposition) or the like. A trench 107 for the wiring layer 101 is formed by RIE using a patterned photo resist as a mask. The trench 107 on left side in FIG. 2A is lower wiring density and the trench 107 on right side in FIG. 2A is higher wiring density. In other words, the wiring on the left side will have greater wiring width than the wiring on the right side.

As shown in FIG. 2B, the barrier layer 102 is formed on an inner surface of the trench 107 and on the first dielectric layer 100 by sputtering or the like. A metal having a Cu as a main component is formed on the barrier layer 102. The metal and the barrier layer provided outside of the trench 107 is removed by a CMP (Chemical Mechanical Polishing). So the barrier layer 102 and the wiring layer 101 provided in the trench 107 are obtained as shown in FIG. 2B.

As shown in FIG. 2C, the cap layer 105 is formed on the wiring layer 101 by electroless plating. The cap layer 105 is self aligned to the wiring layer 101.

The formation of the cap layer 105 is explained.

At first, the exposed top surface of the wiring layer 101 is dip into a PdCl₂ aqueous solution, which has a lower ionization tendency than the Cu, and the Cu atom near the exposed surface is substituted to the Pd atom. The Pd plating layer is formed with self aligned on the top surface of the wiring layer 101. The Pd plating layer functions as a catalyst activation layer, and this is so called an activation of the surface of the wiring.

After activating the top surface of the wiring layer 101, the cap layer 105 is formed with self alignment on the wiring layer 101, on which the catalyst activation is provided, using electroless plating with CoCl₂ as the plating solution. In this embodiment, the cap layer 105 provided on the wiring layer 101 is a material which is better adhesion to the Cu wiring 101 than the conventional cap layer, such as SiC, SiN or the like. So the EM resistance of the wiring layer 101 is improved, since the top surface of the wiring layer 101 is hardly oxidized.

The cap layer 105 is not provided on the first dielectric layer 100, since the first dielectric layer 100 does not contain a metal substituted by the metal atom in the plating solution for forming catalyst activation. So the cap layer 105 is provided on the wiring layer 101, as shown in FIG. 2C. Therefore it is easier to form the cap layer 105 with self alignment than by CVD or the like, since there is not necessary to remove a cap layer 105 provided on the first dielectric layer 100.

The cap layer 105 may be formed by another electroless plating process. For example, after polishing the wiring layer 101 by the CMP process, an acid chemical solution, such as citric acid, hydrochloric acid, a dilute sulfuric acid, which is capable of reacting to a Cu oxide and adding little damage to Cu, is supplied to the wiring layer 101, and an oxide formed on the top surface of the wiring layer 101 is removed by the chemical solution. After that, the top surface of the wiring layer 101 is activated. A sulfuric acid based Co solution, which has a boron (B) or phosphorus (P) and is about 50-100 Centigrade, is supplied to the wiring layer 101.

In case the boron is used as the catalyst, the boron oxide became B3+ after three valence electrons added by Cu, and negative charges, which are supplied by the boron, are accumulated near the top surface of the wiring layer 101. The Co2+ in the sulfuric acid based chemical solution is accumulated near the top surface of the wiring layer 101, and the Co layer 105 (cap layer) is formed on the top surface of the wiring layer 101. On the other hand, the first dielectric layer 100 is not capable of being supplied an electron by the chemical solution, and the Co layer is not formed on the first dielectric layer 100.

After forming the Co layer, the top surface of the wiring layer 101 and the cap layer 105 are cleaned by an acid chemical solution, such as sulfuric acid, hydrofluoric acid, phosphate acid, hydrochloric acid, or the like, and the residual plating solution are removed. The cap layer 105 is stabilized.

As described above, the cap layer 105 is formed on the wiring later 101. However, the cap layer 105 is not formed on the entire top surface of the wiring layer 101. This is because it is hard to form a uniform thickness cap layer 105 on the wiring layer 101, especially a wiring having greater width or provided in a low wiring density region, and deformation of the cap layer and voids in the cap layer may be generated. So, a part of the top surface of the wiring layer 101 is exposed. And the exposed part may be oxidized.

In the cap layer 105 provided on the wiring layer 101, the formation rates between the wiring having large width (left side of the wiring layer 101 shown in FIGS. 2A-2E) and the wiring having smaller width (right side of the wiring layer 101 shown in FIGS. 2A-2E) are different. In other words, the formation rate may be changed on the wiring density. As shown in FIGS. 2A-2E, the wiring 101 having large width or wiring in a low wiring density, which is shown in the left side of the wiring layer 101 shown in FIGS. 2A-2E, has a lower formation rate than the wiring 101 having small width or wiring in a high wiring density, which is shown in the right side of the wiring layer 101 shown in FIGS. 2A-2E. Therefore, the cap layer 105 on the wiring layer 101 does not have a uniform thickness. The cap layer 105 in which the thickness is greater in a local part may be shortened to the neighboring wirings or plugs. The cap layer 105 in which the thickness is less in a local part may not cover the wiring layer 101, the wiring layer 101 is exposed to the ambient, and the wiring layer 101 may be oxidized.

Therefore, in this embodiment, as shown in FIG. 2D, the CuSiN layer 106 is formed on the exposed part of the wiring layer 101 with self alignment. So the top surface of the wiring layer 101 is covered with the cap layer 105 and the CuSiN 106.

After forming the cap layer 105, the semiconductor wafer is provided in the low pressure chamber in about 200-400 Centigrade, and Silane gas is supplied. Si atom from the Silane gas is introduced to the inside wiring layer 101, and the Cu silicide is formed. After that, the ammonia (NH3) gas is supplied to the wafer in a low pressure ambient with high frequency electric field, and an ammonia plasma operation is provided to the wafer. So the Cu silicided is nitridated, and the CuSiN is formed. In case the Si is provided near the top surface of the wiring, the Si atom may be diffused to the inside wiring layer 101 and the electric resistance may be increased. So providing sufficient nitridation may be preferable.

It is easier and better film property to form the uniform thickness CuSiN 106 than the uniform thickness cap layer 105. Thus, the part of the wiring layer 101 which the cap layer 105 is not provided on may be covered with the CuSiN 106.

Thus, a part of top surface of the wiring layer 101 is covered with the cap layer 105, which has high EM resistance, and the rest part of the top surface of the wiring layer 101 is covered with the CuSiN 106. So the interconnect wiring layer which has high EM resistance and is capable of blocking oxidation of the wiring may be obtained.

In the manufacturing process as in FIGS. 2C and 2D, the cap layer 105 is formed to a predetermined thickness, and stopped forming. Later that, the CuSiN 106 is formed on the wiring layer 101. So it may be reduced that an excess formation of the cap layer 105 is provided in the high wiring density region. In case the cap layer 105 on the wiring layer in the low wiring density region is not formed sufficiently, the exposed surface of the wiring 101 is covered with the CuSiN 106.

In the wiring layer 101 in the high wiring density, the EM resistance may be worsened. However, the cap layer 105 which has good EM resistance is provided in the high density region (right side in FIG. 2D).

The anti-oxidation layer which is constituted by the cap layer 105 and the CuSiN layer 106 is better anti-oxidation characteristic and EM resistance and is easy to be manufactured, with comparing to the conventional anti-oxidation layer of the wiring.

As shown in FIG. 2E, the second dielectric layer 103 is deposited on the first dielectric layer 100 by CVD or the like. After that, not be shown in the drawings, a plug electrically connecting to the wiring layer 101 is provided in a hole in the second wiring in the second dielectric layer 103 by using lithography and RIE and the like.

In accordance with the semiconductor device as described above, a part of the top surface of the wiring layer 101 is covered with the cap layer 105 which has a good EM resistance, and the rest part of the top surface of the wiring layer 101, on which the cap layer is not provided, the CuSiN 106 which has a good film property is provided. So the anti-oxidation characteristic of the wiring is improved.

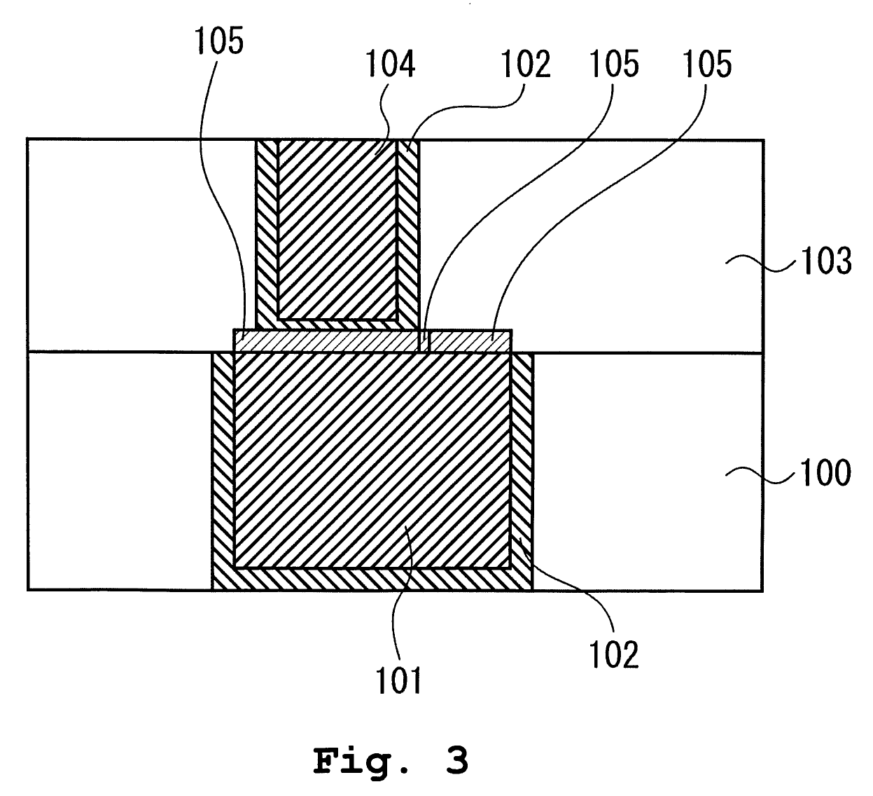

As shown in FIG. 3, it may be available that the CuSiN 106 is not provided on the wiring layer 101. Instead of not providing the CuSiN 106, a part of the top surface of the wiring layer 101, which the cap layer 105 is not formed on, is activated and forming the cap layer process may be done again on the part. So the top surface of the wiring layer 101 may be covered with the cap layer 105.

A semiconductor device, including a dielectric layer, a wiring layer provided in the dielectric layer and having a Cu, a cap layer provided on a top surface of the wiring layer, the cap layer being conductive and having a Co, a Cu silicide which has a nitrogen on the wiring layer except for a region where the cap layer is provided on, is obtained.

Moreover, a semiconductor device, including a dielectric layer, a wiring layer provided in the dielectric layer and having a Cu, a cap layer provided on a top surface of the wiring layer, the cap layer being conductive and having a Co, a Cu silicide which has a nitrogen on the wiring layer except for a region where the cap layer is provided on, and wherein the wiring layer has a first wiring of a first width, and a second wiring of a second width being greater than the first width, and wherein the cap layer is provided on a top surface of the first wiring and the Cu silicide is provided on a top surface of the first wiring except for a region where the cap layer is provided on, and wherein a top surface of the second wiring is covered with the Cu silicide is obtained.

The cap layer 105 and/or the CuSiN 106 may be formed on the barrier layer 102 so as to prevent the barrier layer 102 from being oxidized.

### First Modification of First Embodiment

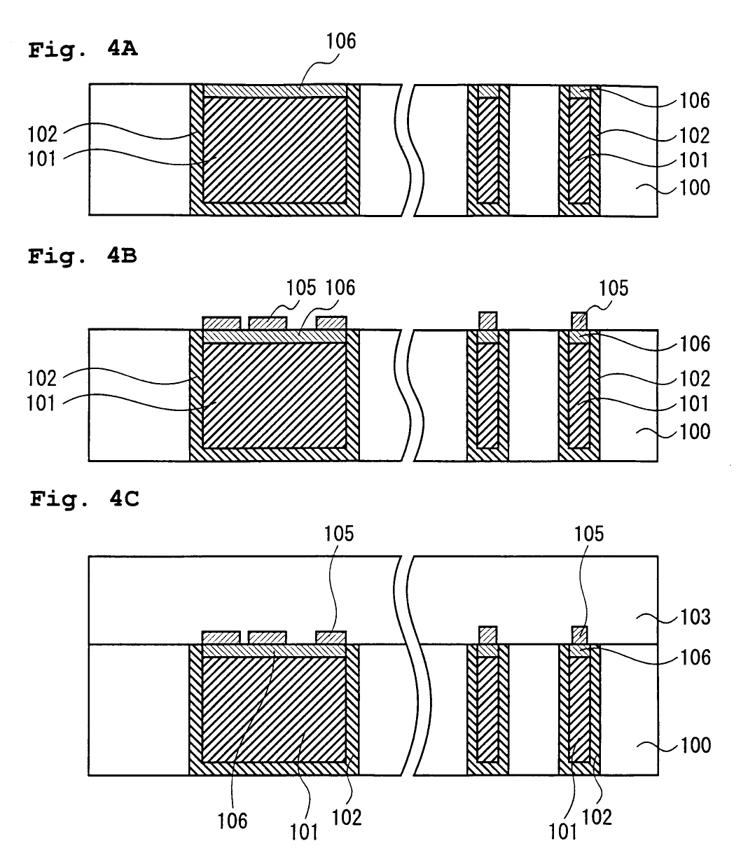

A first modification of the first embodiment is explained with reference to FIGS. 4A-4C.

In this modification, the CuSiN 106 is formed on the wiring layer 106 and the cap layer 105 is formed on the CuSiN 106.

As shown in FIGS. 2A and 2B, the wiring layer 101 is formed in the first dielectric layer 100 via the barrier layer 102.

As shown in FIG. 4A, the CuSiN 106 is formed on the top surface of the wiring layer 101 with self alignment. This CuSiN 106 may be formed as shown in the first embodiment. In this case, by controlling the nitrogen concentration in the CuSiN layer 106, the CuSiN 106 may be formed on the entire top surface of the wiring layer 101.

As shown in FIG. 4B, the cap layer 105 is formed on the CuSiN 106 by electroless plating. This cap layer 105 may be formed as shown in the first embodiment.

The cap layer 105 in accordance with this modification, it may be difficult to form on the CuSiN layer 106, since the cap layer 105 is provided on the Cu in the lower layer.

However, the cap layer 105 is provided on the CuSiN layer 106 at least a part of the CuSiN 106. So at the local part of the wiring layer 101, the anti-oxidation characteristic may be improved.

As shown in FIG. 4C, the second dielectric layer 103 is deposited on the first dielectric layer 100 by CVD or the like. Later that, not shown in the drawings, the plug electrically connecting to the wiring layer 101 is provided in a hole in the second dielectric layer 103. In this process for forming a hole in the second dielectric layer 103, the CuSiN 106 may be partially removed by CF based etchant during RIE process. In this case, the plug is directly in contact with the wiring layer 101.

In the semiconductor device of this modification, the CuSiN 106 is provided on the top surface of the wiring layer 101 and cap layer 105 is provided on a part of the CuSiN 106. So wiring layer with good anti-oxidation may be obtained.

The cap layer 105 and/or the CuSiN 106 may be formed on the barrier layer 102 so as to prevent the barrier layer 102 from being oxidized.

### Second Modification of First Embodiment

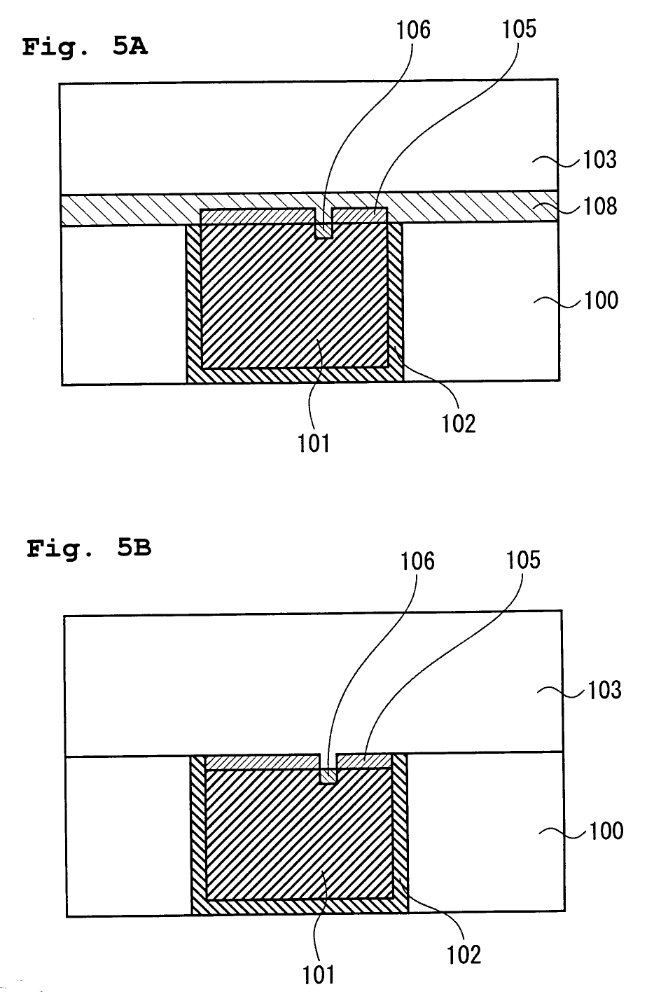

A second modification of the first embodiment is explained with reference to FIGS. 5A-5B.

In this second modification, a dielectric layer in the semiconductor device is different from that in the first embodiment and the first modification thereof.

As shown in FIG. 5A, a barrier dielectric layer 108 is provided between the first dielectric layer 100 and the second dielectric layer 103. The barrier dielectric layer 108 is provided so as to cover the CuSiN 106. The barrier dielectric layer 108 may be SiC layer or SiN layer or the like, which is dielectric and formed by a CVD or the like. The barrier dielectric layer 108 functions as an anti-oxidation layer for the wiring layer 101. So the anti-oxidation characteristic may be improved. Furthermore, a part of the barrier layer 108 provided on or above the wiring layer 101 and the barrier layer 102, such that the capacitance between the wirings are reduced.

In addition, the barrier dielectric layer may be provided on the cap layer 105 in FIG. 3, and provided on the cap layer 105 and the CuSiN 106 so as to cover the cap layer 105 and the CuSiN 106.

As shown in FIG. 5B, the top surface of the cap layer 105 is identical to the top surface of the first dielectric layer 100 or lower than the top surface of the first dielectric layer 100. This structure may be formed by removing the upper part of the wiring layer 101 and forming the cap layer 105 on the wiring layer 101 such that the top surface of the cap layer 105 is identical to the top surface of the first dielectric layer 100 or lower than the top surface of the first dielectric layer 100.

In this structure, the top surface of the cap layer may be identical among those in different wiring density. Namely, a part of the wiring layer 105 in high wiring density region is removed, since the formation rate of the cap layer 105 in the high wiring density region is greater than that in the low wiring density region. So the top surface of the cap layer 105 may be the same among the high wiring density region and the low wiring density region.

A part of the wiring layer 101 may be removed in FIG. 3. A part of the wiring layer 101 may be removed in FIG. 4 before forming the CuSiN 106.

The cap layer 105 and/or the CuSiN 106 may be formed on the barrier layer 102 so as to prevent the barrier layer 102 from being oxidized.

### Second Embodiment

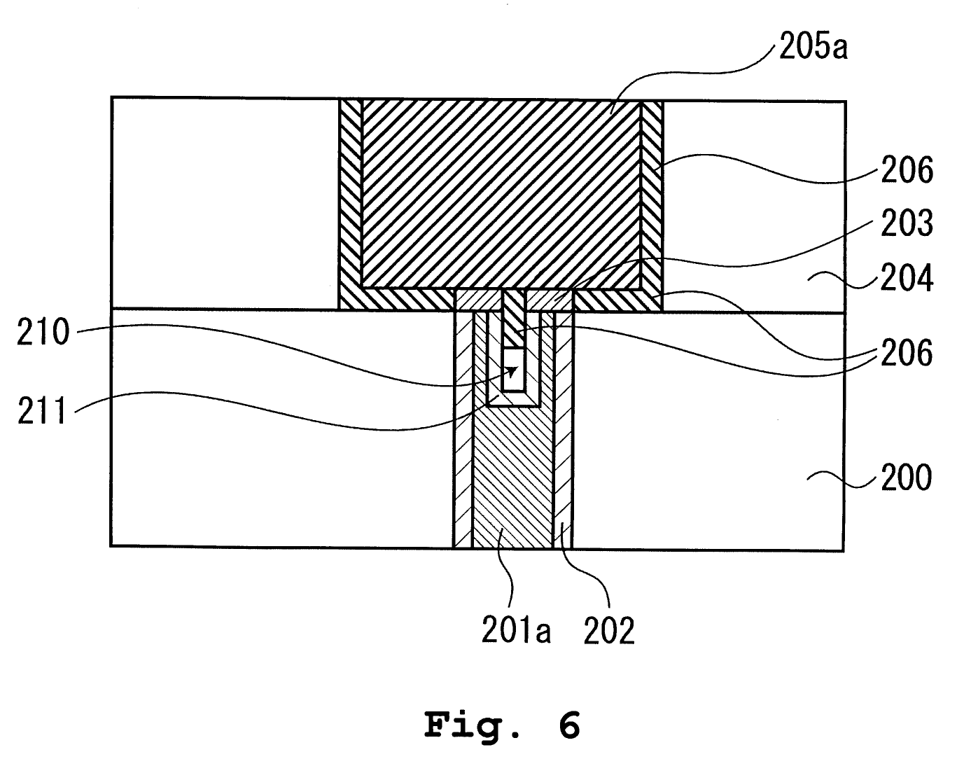

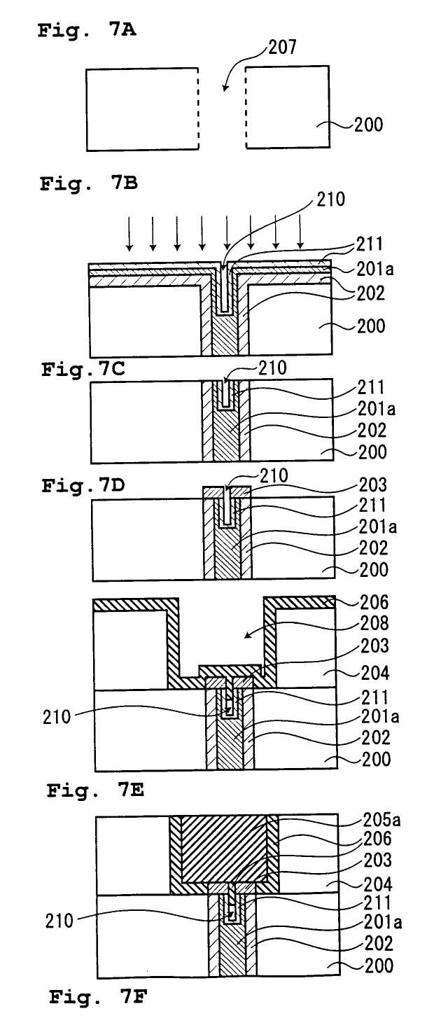

A second embodiment is explained with reference to FIGS. 6-7E.

A semiconductor device and a manufacturing process of the semiconductor device are described in accordance with a second embodiment of the present invention. With respect to each portion of this embodiment, explanation of the same or corresponding portions of the semiconductor device of the first embodiment shown in FIGS. 1-5 is omitted.

FIG. 6 is a cross sectional view of a semiconductor device in accordance with a second embodiment.

In the semiconductor device of this second embodiment, a depression is provided in the plug, and a metal silicide nitride is provided on the inner surface of the depression.

In this second embodiment, a tungsten (W) plug is provided in the first dielectric layer, and a Cu wiring is provided in the second dielectric layer.

As shown in FIG. 6, a tungsten plug 201a, which is penetrated through from the top surface to the bottom surface of the first dielectric layer 200, is provided in the first dielectric layer 200 via a barrier metal 202. The diameter of the plug 201 may be about 30-100 nm, and aspect ratio (plug depth/plug diameter) may be about no less than 5.

In case the diameter of the plug 201a is decreased and the aspect ratio of the plug 201a is increased, a void, seam, and/or depression 210 may be provided on the top surface of the plug 201a.

The barrier layer 202 may be anti-oxidation layer and be made of a TiN, Ti, TaN, Ta or the like, and have about 3-10 nm in thickness. The barrier layer 202 may prevent an oxidation gas and water from introducing into inside of the W plug 201a. The barrier layer 202 may reduce the tungsten atom from the W plug 201a diffusing to the first dielectric layer 200.

A cap layer 203 is provided on the W plug 201a. The cap layer 203 is configured to prevent an impurity component diffusing from the upper side of the plug 201a to the inside of the plug 201a. The cap layer 203 may be a metal which has a high melting point, Co as a component and about 5 nm in thickness, and be made by electroless plating. The cap layer 203 may be CoWB, CoWP, CoWBP, CoBP, CoB, CoP or the like.

A metal silicide nitride layer 211 is provided on the inner surface of the depression 210. The metal silicide nitride layer 211 is configured to prevent the Cu atom in the upper wiring 205a diffusing to the inside of the plug 201a. The metal silicide layer 211 may be W silicide nitride, which is formed by silicidating the surface of the W plug and nitridating the silicidated W.

The metal silicide nitride layer 211 may be capable of being formed a uniform thickness layer in a narrow space, such as void or seam. The metal silicide nitride layer 211 may have a good film property.

The metal silicide nitride layer 211 may be formed as follows.

The inner surface of the plug 201a is exposed to an active gas having Si, such as Silane gas, and exposed to an active gas having N, such as ammonia gas and plasma operation.

The top surface of the plug 201a is covered with the cap layer 203 and the metal silicide nitride 211. The metal silicide nitride 211 is provided on the depression 210, and the cap layer 203 is provided on the metal silicide nitride 211 and the plug 201a. The cap layer 203 may be not provided on the metal silicide nitride 211. The cap layer 203 may be not provided on the barrier layer 202.

A Cu wiring 205a is provided in the second dielectric layer 204 via a barrier layer 206. The wiring 205a is provided on the plug 201a via the cap layer 203, and electrically connected to the plug 201a. The barrier layer 206 may be MnSiO layer, which functions as a diffusion barrier layer.

In FIG. 6, the barrier layer 206 is provided in the depression 210. The barrier layer 206 is in contact with the cap layer 203 and the metal silicide nitride layer 211. A part of the barrier layer 206 is provided in the depression 210. The depression may be filled with the barrier layer 206.

It is hard to fill the depression 210 with the cap layer 203. In case the metal silicide nitride layer 211 is not provided, a part of the top surface of the plug 201a is exposed from the depression 210. So a part of the barrier layer 206 and/or the wiring 205a are/is provided in the depression 210, and a part of the barrier layer 206 and/or the wiring 205a are/is in contact with the plug 201a. In such case, Cu from the barrier layer 206 and/or the wiring 205a may diffuse to the W plug 201a.

However as shown in FIG. 6, when the metal silicide nitride 211 is provided between the plug 201a and the barrier layer 206 and the wiring 205a, the Cu atom may be blocked by the metal silicide nitride 211.

The cap layer 203, which contains Co, may be made by sputtering (PVD: Physical Vapor Deposition), or the like. In case the cap layer 203 is formed by sputtering, the layer may have a thin layer, a uniform film property and good adhesion to the wiring 205a and the electric resistance may be reduced. The cap layer 203 is configured to prevent the Cu diffusing from the wiring 205a to the plug 201a.

The barrier layer 206, which is MnSiO, is formed with self alignment (self forming) between the wiring 205a and the second dielectric layer 204. The MnSiO layer 206 has higher adhesion to the Cu than a conventional barrier layer such as TiN, Ti, TaN and Ta.

Next, the manufacturing process of the semiconductor device as shown in FIG. 6 will be explained hereinafter with reference to FIGS. 7A-7F.

As shown in FIG. 7A, the hole 207 is formed by lithography and RIE in the first dielectric layer 200. The diameter of the hole 207 may be about 50-150 nm, and the aspect ratio is about no less than 5.

As shown in FIG. 7B, the barrier layer or anti-oxidation layer 202, such as TiN, is on the surface of the first dielectric layer 200 and the hole 207. Tungsten for plug is formed on the barrier layer 202.

In this case, it is hard to fill the hole 207 with the tungsten, since the diameter is small and the aspect ratio is large. So, a depression 210 is formed on the top surface of the plug 201a. The bottom of the depression 210 is provided lower than the top surface of the plug 201a.

Next, a tungsten silicide nitride (WSiN) 211 is formed on the surface the 201a. A Silane gas is supplied to the surface of the plug 201a in a low pressure and high temperature (about 200-400 Centigrade) chamber, and tungsten silicide (WSi) is formed. An ammonia plasma operation is provided in the low pressure chamber. Namely, an ammonia gas and high frequency electric field is supplied to the tungsten silicide. So the tungsten silicide is nitridated and the tungsten silicide nitride 211 is formed with self alignment.

As shown in FIG. 7C, the residual first dielectric layer 200, barrier layer 202, tungsten 201a tungsten silicide layer 211 are removed by CMP. The depression 210 is still formed above the plug 201a.

As shown in FIG. 7D, the cap layer 203 is formed on the plug 201a by electroless plating as shown in the process described with FIG. 2C. In this process, the cap layer 203 is not provided on the inner surface of the depression 210.

As shown in FIG. 7E, the second dielectric layer 204 is formed on the first dielectric layer 200, cap layer 203 by CVD or the like. A trench 208 for wiring is formed by lithography and RIE.

A CuMn alloy layer 206, which has 5-100 nm in thickness, is formed on the trench 208 and the second dielectric layer 204. Heat operation (anneal) is provided, Mn in CuMn layer 206 is precipitated on the surface of the second dielectric layer 204 and the first dielectric layer 200, and the MnSiO layer (not shown in FIG. 7E) is formed on the boundary between the CuMn alloy 206 and the first and the second dielectric layers 200, 204. The barrier layer is a self forming barrier layer, which is formed by the CuMn alloy 206 and the second dielectric layer 204.

In the CuMn alloy 206 on the cap layer 203, Mn is diffused toward the dielectric layer. So the Cu (not shown in FIG. 7E) is provided on the cap layer 203.

As shown in FIG. 7E, the CuMn alloy 206 is also provided in the depression 210. However, the tungsten silicide nitride 211 is provided on the plug 201a. So the CuMn alloy 206 is not in contact with the plug 201a, and the Cu is not diffused to inside of the plug 201a.

As shown in FIG. 7F, a Cu 205a is formed in the trench 208 by electric plating, and the Cu 205a and CuMn alloy 206 are removed by CMP such that the second dielectric layer 204 is exposed. So the wiring layer 205a is obtained.

The Cu may be provided in the depression 210, when the top edge of the depression 210 is not covered with the CuMn alloy 206. In such case, the Cu in the wiring layer 205a is hardly diffused to the plug 201a, since the tungsten silicide nitride 211 is provided between the wiring layer 201a and the plug 201a.

As described above, in case the depression, such as a void, seam or the like is provided on the top surface of the plug, a Cu in the barrier layer or the upper wiring layer is hardly diffused to the plug, since a metal silicide nitride layer cap layer are provided between the plug and the upper wiring layer.

### Modification of Second Embodiment

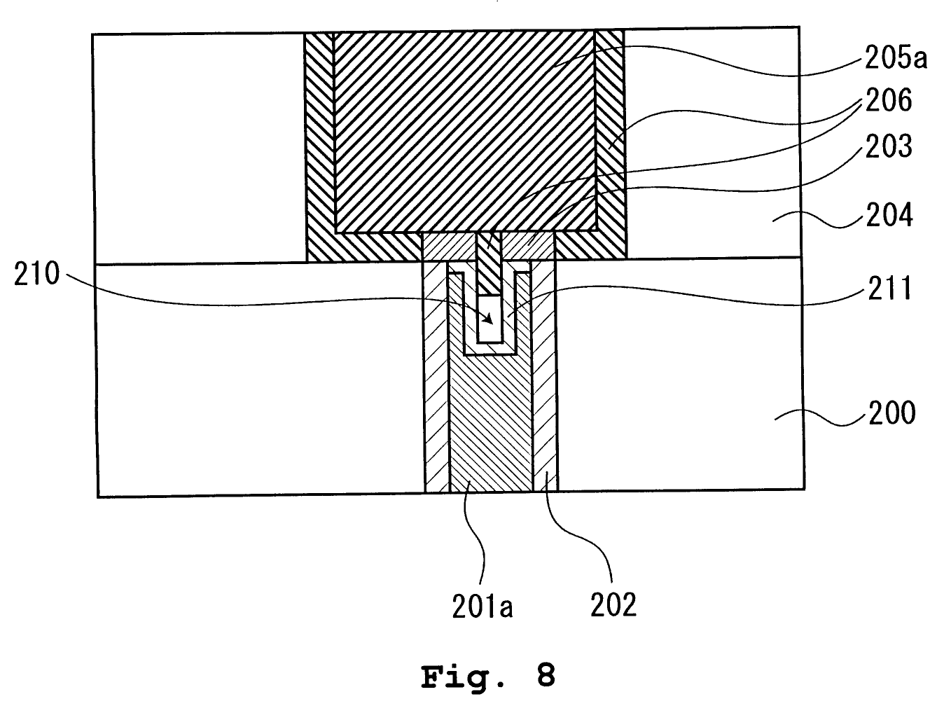

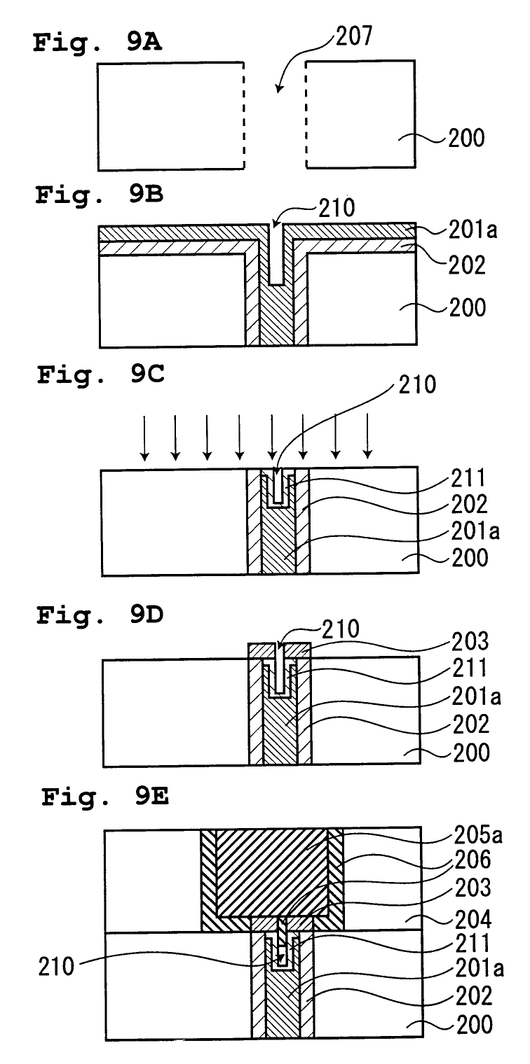

A modification of the first embodiment is explained with reference to FIGS. 8-9E.

In this modification, the metal silicide nitride layer 211 is provided on the top surface of the plug 201a, and the cap layer 203 is provided on the top surface of the plug 201a via the plug 201a.

The manufacturing process of the semiconductor device as shown in FIG. 8 will be explained with reference to FIGS. 9A-9E.

As shown in FIG. 9A, the hole 207 is formed by lithography and RIE in the first dielectric layer 200.

As shown in FIG. 9B, the barrier layer or anti-oxidation layer 202, such as TiN, is on the surface of the first dielectric layer 200 and the hole 207.

As shown in FIG. 9C, the tungsten 201a, barrier layer 202 and first dielectric layer 200 is removed by CMP, such that the first dielectric layer 200 is exposed. So, a depression 210 is formed on the top surface of the plug 201a.

Next, a tungsten silicide nitride (WSiN) 211 is formed on the surface the 201a. A Silane gas is supplied to the surface of the plug 201a, and tungsten silicide (WSi) is formed. After that, the tungsten silicide is nitridated and the tungsten silicide nitride 211 is formed with self alignment. Thus the tungsten silicide nitride is formed on the exposed surface of the plug 201a which is inner surface of the depression 210 and the top surface of the plug 201a.

As shown in FIG. 9D, the cap layer 210, which has a Co, is formed on the tungsten silicide layer 211 and the barrier layer 202.

As shown in FIG. 9E, the second dielectric layer 204 is formed, the barrier layer 206 is formed, and the wiring layer 205a is formed in this order.

The semiconductor device in accordance with this modification, on the top surface of the plug, two layers, which have the metal silicide nitride layer and the cap layer, are provided between the plug and the upper wiring. So it is difficult that the Cu in the upper wiring is diffused to the plug, since the Cu is blocked by the two layers.

Embodiments of the invention have been described with reference to the examples. However, the invention is not limited thereto.

The plug 201a may be tungsten (W), aluminum (Al), cobalt (Co), or the like.

The metal silicide nitride may be provided on the top surface of the Cu wiring layer 205a. In this case, a Cu silicide nitride is provided on the Cu wiring layer and a W plug is provided on the Cu silicide nitride layer via a Co cap layer. So the Cu in the lower wiring layer having Cu atom is hardly diffused to the upper plug, since the Cu is blocked by the Cu silicide nitride provided between the lower Cu wiring and the upper plug.

A layer including at least one metal from a group of Mn, Nb, Zr, Cr, V, Y, Tc, Re, and oxygen (O) may be provided between the Cu wiring and the dielectric.

The barrier dielectric layer 108 as shown in FIG. 5A may be provided in the semiconductor device in the first and second embodiment and their modification.

The top surface of the cap layer in the first and second embodiment and their modification may be identical to or lower than the top surface of the first dielectric layer 100.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A method of manufacturing a semiconductor device, comprising:
providing a first dielectric layer;
providing a trench in the first dielectric layer and a wiring layer which has a Cu in the trench;
providing a cap layer on a top surface of the wiring layer, the cap layer being conductive and having a Co; and
providing a Cu silicide nitride layer on a part of the top surface of the wiring layer, on which the cap layer is not provided.

2. A method of manufacturing a semiconductor device of claim 1,
wherein the wiring layer has a first wiring and a second wiring provided in lower wiring density region than the first wiring, and
wherein providing a cap layer comprises providing a cap layer on a top surface of the first wiring and a top surface of the second wiring, and
providing a Cu silicide nitride layer comprises providing a Cu silicide nitride on a part of the top surface of the second wiring, on which the cap layer is not provided.

3. A method of manufacturing a semiconductor device of claim 2,
wherein providing a cap layer comprises providing a cap layer on a top surface of the first wiring so as to cover the top surface of the first wiring and on a top surface of the second wiring with a part of the top surface of the second wiring exposed, and
providing a Cu silicide nitride layer comprises providing a Cu silicide nitride layer on the top surface of the exposed surface of the second wiring.

4. A method of manufacturing a semiconductor device, comprising:
providing a first dielectric layer;
providing a trench in the first dielectric layer and a wiring layer which has a Cu in the trench;
providing a first cap layer on a top surface of the wiring layer, the first cap layer being conductive and having a Co;
activating at least a part of the top surface of the wiring layer, on which the first cap layer is not provided; and
providing a second cap layer on the activated part of the wiring layer, the second cap layer being conductive and having a Co.

5. A method of manufacturing a semiconductor device of claim 4,
wherein the wiring layer has a first wiring and a second wiring provided in lower wiring density region than the first width, and
wherein providing a first cap layer comprises providing a first cap layer on a top surface of the first wiring and a top surface of the second wiring, and
providing a second cap layer comprises providing a second cap layer on a top surface of the second wiring.

6. A method of manufacturing a semiconductor device of claim 5,
wherein providing a first cap layer comprises providing a first cap layer on the top surface of the first wiring so as to cover the top surface of the first wiring and on the top surface of the second wiring with a part of the top surface of the second wiring exposed, and
wherein providing a second cap layer comprises providing a first cap layer on a top surface of the first wiring and a top surface of the second wiring, and
providing a second cap layer comprises providing a second cap layer on the top surface of the exposed surface of the second wiring.

7. A method of manufacturing a semiconductor device of claim 4,
wherein the first cap layer and the second cap layer are same materials.

8. A method of manufacturing a semiconductor device of claim 6,
wherein the first cap layer and the second cap layer are same materials.

9. A method of manufacturing a semiconductor device, comprising:
providing a first dielectric layer;
providing a trench in the first dielectric layer and a wiring layer which has a Cu in the trench;
providing a Cu silicide nitride layer on a top surface of the wiring layer;
providing a cap layer on a top surface of the Cu silicide nitride layer, the cap layer being conductive and having a Co.

10. A semiconductor device, comprising:
a dielectric layer;
a wiring layer provided in the dielectric layer and having a Cu;
a cap layer provided on a top surface of the wiring layer, the cap layer being conductive and having a Co;
a Cu silicide nitride layer on the wiring layer except for a region where the cap layer is provided on.

11. A semiconductor device of claim 10, wherein the wiring layer has a first wiring and a second wiring provided in lower wiring density region than the first width, and
wherein the cap layer is provided on a top surface of the first wiring and the Cu silicide nitride layer is provided on a top surface of the first wiring except for a region where the cap layer is provided on, and
wherein a top surface of the second wiring is covered with the Cu silicide nitride layer.

12. A semiconductor device, comprising:
a first wiring member having a metal (M) and having a depression on a top surface;
a cap layer provided on a top surface of the first wiring, the cap layer being conductive and having a Co;
a second wiring member provided on the cap layer; and
a metal silicide nitride layer having the M as a component provided on a surface of the depression,
wherein one of the first wiring member and the second wiring member has a Cu as a main component.

13. A semiconductor device of claim 12, wherein the cap layer is provided on the top surface of the metal silicide nitride layer.

14. A semiconductor device of claim 12, wherein the first wiring member is a W plug, and the second wiring member is a Cu wiring.

15. A semiconductor device of claim 12, wherein the second wiring member is provided in a dielectric via a barrier layer, and the barrier layer is provided on the metal silicide nitride layer.

16. A semiconductor device of claim 12, wherein the second wiring member is provided in a dielectric via a barrier layer, and the barrier layer is provided on the metal silicide nitride layer and the cap layer.

17. A semiconductor device of claim 12, wherein the M silicide is provided on the top surface of the first wiring member, and the cap layer is provided on the top surface of the first wiring member via the metal silicide nitride layer.

18. A semiconductor device of claim 17, wherein the first wiring member is a W plug, and the second wiring member is a Cu wiring.

19. A semiconductor device of claim 17, wherein the second wiring member is provided in a dielectric via a barrier layer, and the barrier layer is provided on the metal silicide nitride layer.

20. A semiconductor device of claim 17, wherein the second wiring member is provided in a dielectric via a barrier layer, and the barrier layer is provided on the metal silicide nitride layer and the cap layer.
